(19) United States
(12) Patent Application Publication
(10) Pub. No.: US 2015/0064621 A1
(43) Pub. Date: Mar. 5, 2015

(54) SUBSTRATE TREATMENT DEVICE AND METHOD OF APPLYING TREATMENT SOLUTION

(71) Applicant: Semes Co., Ltd., Cheonan-si (KR)

(72) Inventors: Jung Yul LEE, Cheonan-si (KR); Choong Ki MIN, Cheonan-si (KR); Jeong Soo KIM, Hwaseong-si (KR)

(21) Appl. No.: 14/472,986

(22) Filed: Aug. 29, 2014

(30) Foreign Application Priority Data
Aug. 30, 2013 (KR) 10-2013-0104072
Dec. 27, 2013 (KR) 10-2013-0165400

(51) Int. Cl. G03F 7/16; B05B 1/16; B05B 3/00; B05C 11/08; B05C 11/10

(52) U.S. Cl. CPC G03F 7/162; B05C 11/08; B05C 11/10; B05B 3/00; B05B 1/16
USPC 430/270.1; 118/52

(57) ABSTRACT

Provided is a substrate treatment device. The device includes: a substrate support member supporting a substrate to be treated; a rotation driving member rotating the substrate support member; a container provided around the substrate support member; and a treatment solution supply unit including a photoresist nozzle for supplying a photoresist to a top surface of the substrate, wherein the photoresist nozzle starts supplying the photoresist while the substrate support member rotates at a first supply speed and stops supplying the photoresist while the substrate support member rotates at a second supply speed decelerated from the first supply speed.

### CROSS-REFERENCE TO RELATED APPLICATIONS

This U.S. non-provisional patent application claims priority under 35 U.S.C. §119 of Korean Patent Application Nos. 10-2013-0104072, filed on Aug. 30, 2013, and 10-2013-0165400, filed on Dec. 27, 2013, the entire contents of which are hereby incorporated by reference.

### BACKGROUND OF THE INVENTION

The present invention relates to a substrate treatment device and a method of applying a treatment solution.

In order to fabricate a semiconductor device, various processes, for example, cleaning, deposition, photolithography, etching, and ion implantation, are performed. A photolithography process for forming a pattern plays a very important role to achieve the high integration of a semiconductor device.

The photolithography process is performed by coating a photoresist on a substrate. The coating process for the photoresist may be performed while a substrate rotates. If the amounts of a photoresist coated on each area of a substrate are different, a defective substrate may be caused.

### SUMMARY OF THE INVENTION

The present invention provides a substrate treatment device treating a substrate uniformly and a method of applying a treatment solution.

The present invention also provides a substrate treatment device coating a photoresist on a substrate uniformly and a method of applying a treatment solution.

Embodiments of the present invention provide substrate treatment devices including: a substrate support member configured to support a substrate to be treated; a rotation driving member rotating the substrate support member; a container provided around the substrate support member; and a treatment solution supply unit including a photoresist nozzle for supplying a photoresist to a top surface of the substrate, wherein the photoresist nozzle starts supplying the photoresist while the substrate support member rotates at a first supply speed and stops supplying the photoresist while the substrate support member rotates at a second supply speed decelerated from the first supply speed.

In some embodiments, the rotation driving member may rotate the substrate support member at a diffusion speed accelerated from the second supply speed after the photoresist supply is terminated.

In other embodiments, the diffusion speed may be set to be less than the first supply speed and greater than the second supply speed.

In still other embodiments, the rotation driving member may rotate the substrate support member at a termination speed decelerated from the diffusion speed and then stops the substrate support member.

In even other embodiments, the rotation driving member gradually may reduce a rotational speed of the substrate support member from the first supply speed to the second supply speed.

In yet other embodiments, the rotation driving member may rotate the substrate support member at a buffer speed for a predetermined time while the first supply speed is decelerated to the second supply speed.

In further embodiments, the treatment solution supply unit may include: a nozzle arm having one end where the photoresist nozzle is positioned; and a driving member moving the nozzle arm with respect to the substrate support member, wherein the stop of the photoresist supply may be made when the driving member positions the nozzle arm to allow the photoresist nozzle to be positioned above the center of the substrate.

In still further embodiments, the start of the photoresist supply may be made when the driving member positions the nozzle arm to allow the photoresist nozzle to be positioned eccentrically above the center of the substrate.

In even further embodiments, after the start of the photoresist supply, the driving member may move the nozzle arm to allow the photoresist nozzle to be positioned above the center of the substrate.

In yet further embodiments, the photoresist nozzle may supply the photoresist for a predetermined time as being positioned above the center of the substrate.

In yet further embodiments, the treatment solution supply unit may further include a pre-wet nozzle for supplying an organic solvent to the substrate.

In yet further embodiments, the pre-wet nozzle may supply the organic solvent to the substrate before the photoresist supply.

In yet further embodiments, the treatment solution supply unit may supply the organic solvent to the substrate while the pre-wet nozzle is positioned above the center of the substrate.

In other embodiments of the present invention, provided are methods of applying a treatment solution. The methods include: starting to supply a photoresist to a top surface of a substrate supported by a substrate support member rotating at a first supply speed, and stopping the photoresist supply while the substrate support member is decelerated from the first supply speed to a second supply speed.

In some embodiments, the methods may further include, after the photoresist supply is terminated, rotating the substrate support member at a diffusion speed accelerated from the second supply speed and diffuses the photoresist gathered on a center portion of the substrate to a periphery of the center.

In other embodiments, the methods may further include rotating the substrate support member for a predetermined time at a termination speed decelerated from the diffusion speed and stopping the rotation.

In still other embodiments, the methods may further include gradually decelerating the first supply speed to the second supply speed.

In even other embodiments, the photoresist supply may start from a position eccentric from the center of the substrate and may move to the center of the substrate.

In yet other embodiments, the photoresist supply may stop while the photoresist is supplied to the center of the substrate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view of a substrate treatment device as seen from the top;

FIG. 2 is a view illustrating a device of FIG. 1 as seen from a direction A-A;

FIG. 3 is a view illustrating a device of FIG. 1 as seen from a direction B-B;

FIG. 4 is a view illustrating a device of FIG. 1 as seen from a direction C-C;

FIG. 5 is a plan view of a coating module according to an embodiment of the present invention;

FIG. 6 is a cross-sectional view illustrating a coating module of FIG. 5;

FIG. 7 is a front view when an organic solvent is supplied from a pre-wet nozzle during an organic solvent supply process;

FIG. 8 is a front view when a photoresist is supplied during an eccentric supply process;

FIG. 9 is a front view when a photoresist is supplied during a center supply process;

FIG. 10 is a front view illustrating a diffusion stage;

FIG. 11 is a graph illustrating the rotational speed of a support plate in a photoresist supply stage and a diffusion stage; and

FIG. 12 is a graph illustrating the rotational speed of a support plate according to another embodiment of the present invention.

### DETAILED DESCRIPTION OF PREFERRED EMBODIMENTS

Hereinafter, various embodiments of the present invention will be described with reference to the accompanying drawings. However, embodiments of the present invention may be modified in various forms, and the scope of the present invention is not limited to the following embodiments. These embodiments are provided so that the present invention will be further completely described to those skilled in the art. Accordingly, the forms of elements in the drawings are exaggerated for clarity of description.

Equipment of this embodiment is used for performing a photolithography process on a substrate, for example, a semiconductor wafer or a flat display panel. Especially, the equipment of this embodiment is used to perform a coating process on a substrate, a development process, and a pre/post-exposure treatment process that is required before/after an immersion exposure. Hereinafter, the case that a substrate is used as wafer is described as an example.

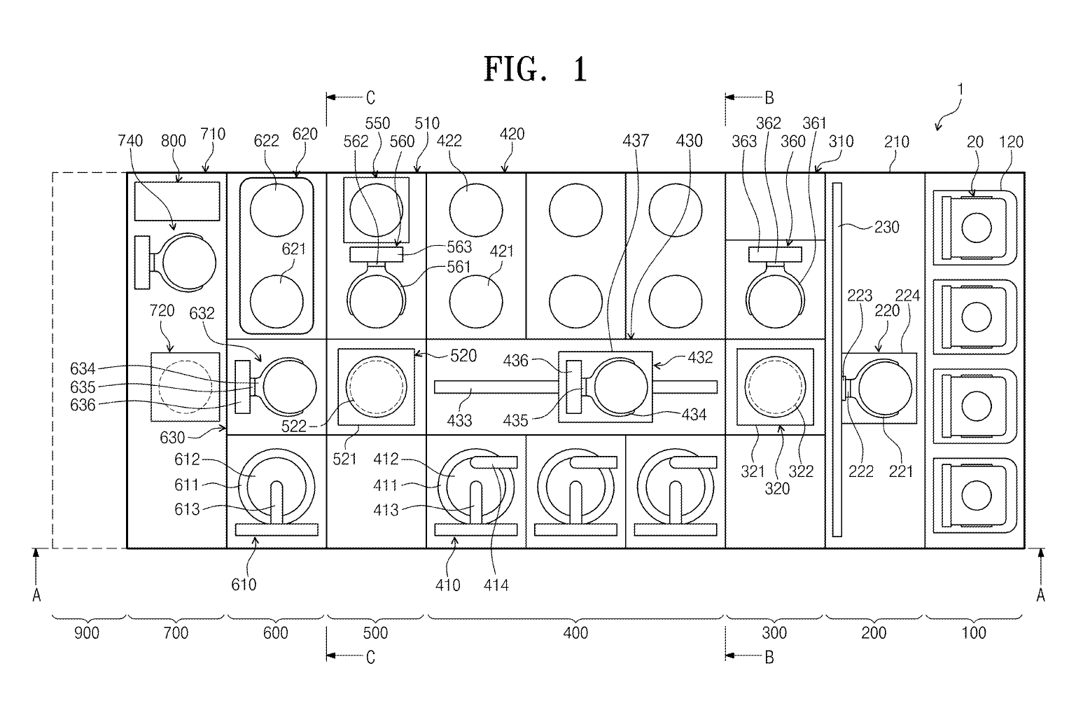

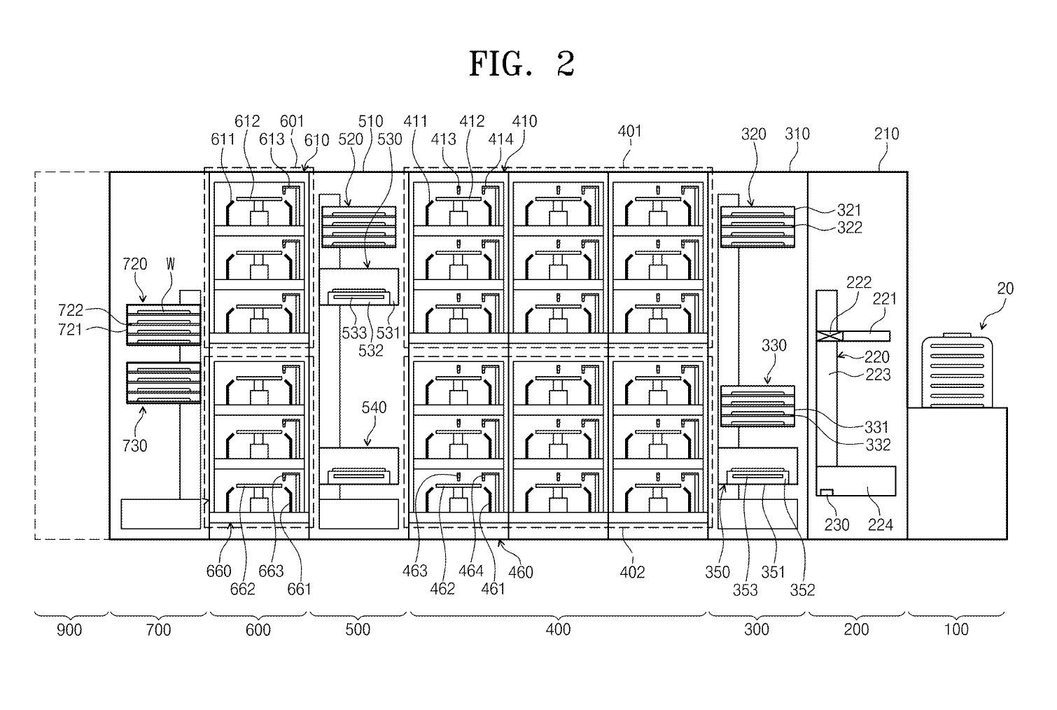

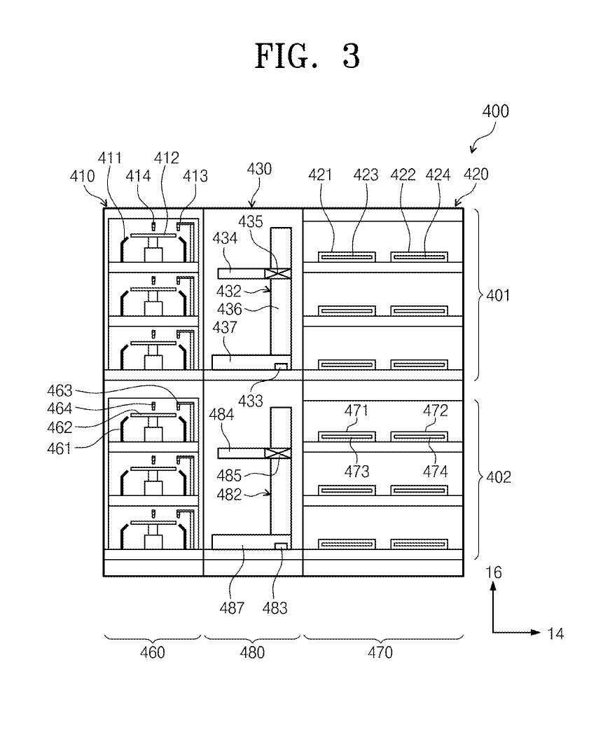

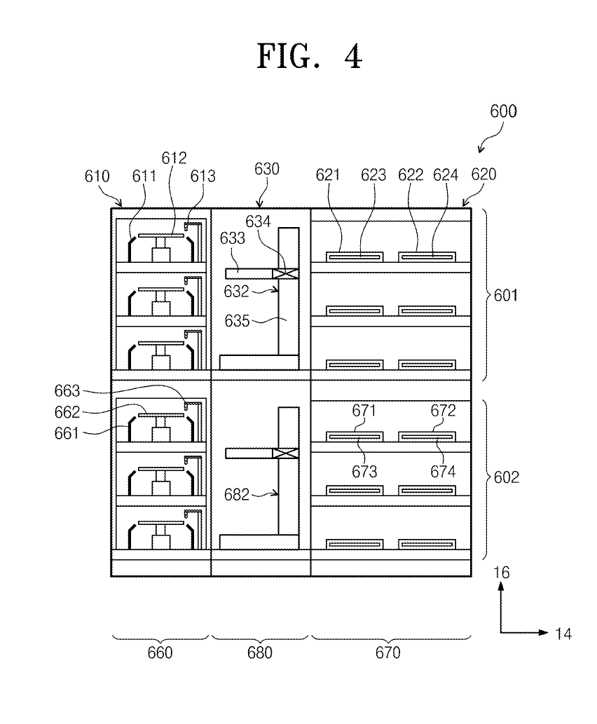

FIGS. 1 to 4 are views illustrating a substrate treatment device according to an embodiment of the present invention. FIG. 1 is a view illustrating a substrate treatment device as seen from the top. FIG. 2 is a view illustrating the device of FIG. 1 as seen from a direction A-A. FIG. 3 is a view illustrating the device of FIG. 1 as seen from a direction B-B. FIG. 4 is a view illustrating the device of FIG. 1 as seen from a direction C-C.

Referring to FIGS. 1 to 4, the substrate treatment device 1 includes a rod port 100, an index module 200, a first buffer module 300, a coating and development module 400, a second buffer module 500, an exposure before/before treatment module 600, an interface module 700, and a fuzzy module 800. The rod port 100, the index module 200, the first buffer module 300, the coating and development module 400, the second buffer module 500, the exposure before/before treatment module 600, and the interface module 700 are sequentially disposed in a line in one direction. The fuzzy module 800 may be provided in the interface module 700. Unlike this, the fuzzy module 800 may be provided at various positions, for example, a position where an exposure device 900 at the rear end of the interface module 700 is connected or a side part of the interface module 700.

Hereinafter, a direction in which the rod port 100, the index module 200, the first buffer module 300, the coating and development module 400, the second buffer module 500, the exposure before/before treatment module 600, and the interface module 700 are disposed is referred to as a first direction 12. A direction vertical from the first direction 12, as seen from the top, is referred to as a second direction 14. A direction vertical to the first direction 12 and the second direction 14 is referred to as a third direction 16.

A wafer W moves while received in a cassette 20. At this point, the cassette 20 has a structure sealed from the outside. For example, a front open unified pod (FOUP) having a door at the front may be used as the cassette 20.

Hereinafter, the rod port 100, the index module 200, the first buffer module 300, the coating and development module 400, the second buffer module 500, the exposure before/before treatment module 600, the interface module 700, and fuzzy module 800 will be described in more detail.

(Rod Port)

The rod port 100 has a support table 120 where the cassette 20 having received wafers W is disposed. A plurality of support tables 120 are provided and arranged in a line along the second direction 14. Four support tables 120 are provided as shown in FIG. 1.

(Index Module)

The index module 200 transfers a wafer W between the cassette 20 and the first buffer module 300 on the support table 120 of the rod port 100. The index module 200 includes a frame 210, an index robot 220, and a guide rail 230. The frame 210 has a rectangular form with an empty inside and is disposed between the rod port 100 and the first buffer module 300. The frame 210 of the index module 200 may be provided lower than a frame 310 of a first buffer module 300 described later. The index robot 200 and the guide rail 230 are disposed in the frame 210. The index robot 220 has a 4-axis driving structure for allowing a hand 221 that directly handles the wafer W to move and rotate in the first direction 12, the second direction 14, and the third direction 16. The index robot 220 includes the hand 221, an arm 222, a support 223, and a stand 224. The hand 221 is fixedly installed to the arm 222. The arm 222 is provided with a stretchable structure and a rotatable structure. The support 223 has a length direction that is disposed along the third direction 16. The arm 222 is coupled to the support 223 to move along the support 223. The support 223 is fixedly coupled to the stand 224. The guide rail 230 is provided with its length direction disposed along the second direction 14. The stand 224 is coupled to the guide rail 230 to linearly move along the guide rail 230. Additionally, although not shown in the drawing, a door opener opening/closing the door of the cassette 20 is further provided to the frame 210.

(First Buffer Module)

The first buffer module 300 includes a frame 310, a first buffer 320, a second buffer 330, a cooling chamber 350, and a first buffer robot 360. The frame 310 has a rectangular form with an empty inside and is disposed between the index module 200 and the coating and development module 400. The first buffer 320, the second buffer 330, the cooling chamber 350, and the first buffer robot 360 are disposed in the frame 310. The cooling chamber 350, the second buffer 330, and the first buffer 320 are disposed along the first direction 16 sequentially from the bottom. The first buffer 320 is positioned at the height corresponding to a coating module 401 of the coating and development module 400 and the second buffer 330 and the cooling chamber 350 are positioned at the height corresponding to a development module 402 of the coating and development module 400. The first buffer robot 360 is spaced a predetermined distance in the second direction 14 from the second buffer 330, the cooling chamber 350, and the first buffer 320.

The first buffer 320 and the second buffer 330 store a plurality of wafers W temporarily. The second buffer 330 has a housing 331 and a plurality of supports 332. The supports 332 are disposed in the housing 331 and are provided spaced apart from each other in the third direction 16. One wafer W is disposed at each support 332. The housing 331 has an opening (not shown) in a direction where the index robot 220 is provided, a direction where the first buffer robot 350, and a direction where a development unit robot 482 described later is provided, so as to allow the index robot 220, the first buffer robot 360, and the development unit robot 482 of the development module 402 to carry the wafer W into or from the support 332 in the housing 331. The first buffer 320 has a relatively similar structure to the first buffer 330. However, the hosing 321 of the first buffer 320 has an opening in a direction where the first buffer robot 360 is provided and in a direction where a coating unit robot 432 in the coating module 401 is provided. The number of the supports 322 provided in the first buffer 320 may be different from or identical to the number of the supports 332 provided in the second buffer 330. For example, the number of the supports 322 provided in the second buffer 330 may be different from or identical to the number of the supports 322 provided in the first buffer 320.

The first buffer robot 360 transfers the wafer W between the first buffer 320 and the second buffer 330. The first buffer robot 360 includes a hand 361, an arm 362, and a support 363. The hand 361 is fixedly installed to the arm 362. The arm 362 has a stretchable structure to allow the hand 361 to move along the second direction 14. The arm 362 is coupled to the support 363 to linearly move along the support 363 in the third direction 16. The support 363 has an extended length from the position corresponding to the first buffer 330 to the position corresponding to the first buffer 320. The support 363 may be further longer in an above or below direction thereof. The first buffer robot 360 may be provided to allow the hand 361 to be simply 2-axis-driven according to the second direction 14 and the third direction 16.

The cooling chamber 350 cools each wafer W. The cooling chamber 350 includes a housing 351 and a cooling plate 352. The cooling plate 352 includes a cooling means 353 cooling the top surface where the wafer W is disposed and the wafer W. Various methods, for example, cooling by coolant or cooling by a thermoelectric device, may be used for the cooling means 353. Additionally, a lift pin assembly (not shown) positioning the wafer W on the cooling plate 352 may be provided to the cooling chamber 350. The housing 351 has an opening (not shown) in a direction where the index robot 220 is provided and a direction where the development unit robot 482 is provided, so as to allow the index robot 220 and the development unit robot 482 of the development module 402 to carry the wafer W into or from the cooling plate 352. Additionally, doors (not shown) opening/closing the opening may be provided to the cooling chamber 350.

(Coating and Development Module)

The coating and development module 400 performs a process for coating a photoresist on the wafer W before an exposure process and a process for developing the wafer W after the exposure process. The coating and development module 400 has a relatively rectangular parallelepiped form. The coating and development module 400 includes a coating module 401 and a development module 402. The coating module 401 and the development module 402 are disposed to be partitioned from each other by a layer. According to an embodiment of the present invention, the coating module 401 is disposed on the development module 402.

The coating module 401 includes a process for coating a photoresist on the wafer W and a thermal treatment process for heating and cooling the wafer W before/after the resist coating process. The coating module 401 includes a resist coating chamber 410, a bake chamber 420, and a conveying chamber 430. The resist coating chamber 410, the bake chamber 420, and the conveying chamber 430 are sequentially disposed along the second direction 14. Accordingly, the resist coating chamber 410 and the bake chamber 420 are spaced from each other in the second direction with the conveying chamber 430 therebetween. A plurality of resist coating chambers 410 are provided in each of the first direction 12 and the third direction 16. In the drawings, six resist coating chambers 410 are provided. A plurality of bake chambers 420 are provided in each of the first direction 12 and the third direction 16. In the drawings, six bake chambers 420 are provided. Unlike this, the more number of bake chambers 420 may be provided.

The conveying chamber 430 is positioned parallel to the first buffer 320 of the first buffer module 300 in the first direction 12. A coating unit robot 432 and a guide rail 433 are positioned in the conveying chamber 430. The conveying chamber 430 typically has a rectangular form. The coating unit robot 432 transfers the wafer W between the bake chambers 420, the resist coating chambers 400, the first buffer 320 of the first buffer module 300, and the first cooling chamber 520 of the second buffer module 500. The guide rail 433 is disposed with its length direction parallel to the first direction 12. The guide rail 433 guides the coating unit robot 432 to linearly move in the first direction 12. The coating unit robot 432 includes a hand 434, an arm 435, a support 436, and a stand 437. The hand 434 is fixedly installed to the arm 435. The arm 435 has a stretchable structure to allow the hand 434 to move in a horizontal direction. The support 436 is provided with its length direction that is disposed along the third direction 16. The arm 435 is coupled to the support 436 to linearly move along the support 363 in the third direction 16. The support 436 is fixedly coupled to the stand 437 and the stand 437 is coupled to the guide rail 433 to move linearly move along the guide rail 230.

The resist coating chambers 410 have the same structure. However, types of a photoresist used in each resist coating chamber 410 may be different from each other. For example, a chemical amplification resist may be used as a photoresist. The resist coating chamber 410 coats the wafer W with a photoresist. The resist coating chamber 410 includes a housing 411, a support plate 412, and a nozzle 413. The housing 411 has a cup form with an open top. The support plate 412 is disposed in the housing 411 and supports the wafer W. The support plate 412 is provided to be rotatable. The nozzle 413 supplies a photoresist to the top of the wafer W disposed on the support plate 412. The nozzle 413 may have a circular pipe form and may supply a photoresist to the center of the wafer W. Selectively, the nozzle 413 may have a length corresponding to the diameter of the wafer W and a discharge port of the nozzle 413 may be provided as a slit. Additionally, the resist coating chamber 410 may further include a nozzle 414 for supplying a cleaning fluid such as deionized water to clean the surface of the wafer W where the photoresist is coated.

The bake chamber 420 performs a thermal treatment on the wafer W. For example, the bake chamber 420 performs a prebake process for removing organic matters or moistures of the surface of the wafer W by heating the wafer W to a predetermined temperature before applying the photoresist or a soft bake process after applying the photoresist on the wafer W, and then performs a cooling process for cooling the wafer W after each heating process. The bake chamber 420 includes a cooling plate 421 or a heating plate 422. A cooling means 423 such as coolant or a thermoelectric device is provided to the cooling plate 421. Additionally, a heating means 424 such as a heating wire or a thermoelectric device is provided to the heating plate 422. The cooling plate 421 and the heating plate 422 may be separately provided in one bake chamber 420. Selectively, part of the bake chamber 420 may include only the cooling plate 421 and another part may include only the heating plate 422.

The development module 402 includes a development process for removing a portion of the photoresist by supplying a developer to obtain a pattern on the wafer W and a thermal treatment process such as heating and cooling on the wafer W before/after the development process. The development module 5402 includes a development chamber 460, a bake chamber 470, and a conveying chamber 480. The development chamber 460, the bake chamber 470, and the conveying chamber 480 are sequentially disposed along the second direction 14. Accordingly, the development chamber 460 and the bake chamber 470 are spaced from each other in the second direction with the conveying chamber 480 therebetween. A plurality of development chambers 460 are provided in each of the first direction 12 and the third direction 16. In the drawings, six development chambers 460 are provided. A plurality of bake chambers 470 are provided in each of the first direction 12 and the third direction 16. In the drawings, six bake chambers 470 are provided. Unlike this, the more number of bake chambers 470 may be provided.

The conveying chamber 480 is positioned parallel to the second buffer 330 of the first buffer module 300 in the first direction 12. The development unit robot 482 and the guide rail 483 are positioned in the conveying chamber 480. The conveying chamber 480 typically has a rectangular form. The development unit robot 482 transfers the wafer W between the bake chambers 470, the development chambers 460, the second buffer 330 and the cooling chamber 350 of the first buffer module 300, and the second cooling chamber 540 of the second buffer module 500. The guide rail 483 is disposed with its length direction parallel to the first direction 12. The guide rail 483 guides the development unit robot 482 to linearly move in the first direction 12. The development unit robot 482 includes a hand 484, an arm 485, a support 486, and a stand 487. The hand 484 is fixedly installed to the arm 485. The arm 485 has a stretchable structure to allow the hand 484 to move in a horizontal direction. The support 486 is provided with its length direction that is disposed along the third direction 16. The arm 485 is coupled to the support 486 to linearly move along the support 363 in the third direction 16. The support 486 is fixedly coupled to the stand 487. The stand 487 is coupled to the guide rail 483 to move along the guide rail 483.

The development chambers 460 have the same structure. However, types of a photoresist used in each development chamber 460 may be different from each other. The development chamber 460 removes an irradiated area of the photoresist on the wafer W. At this point, an irradiated area in a protective layer is removed together. Selectively, according to the types of a photoresist in use, only the area that is not irradiated with light may be removed from areas of a photoresist and a protective layer.

The development chamber 460 includes a housing 461, a support plate 462, and a nozzle 463. The housing 461 has a cup form with an open top. The support plate 462 is disposed in the housing 461 and supports the wafer W. The support plate 462 is provided to be rotatable. The nozzle 463 supplies a developer to the top of the wafer W disposed on the support plate 462. The nozzle 463 has a circular pipe form and supplies a developer to the center of the wafer W. Selectively, the nozzle 463 may have a length corresponding to the diameter of the wafer W and a discharge port of the nozzle 463 may be provided as a slit. Additionally, the development chamber 460 may further include a nozzle 464 for supplying a cleaning fluid such as deionized water to clean the surface of the wafer W where the developer is supplied.

The bake chamber 470 performs a thermal treatment on the wafer W. For example, the bake chamber 470 performs a post bake process for heating the wafer W before performing a development process, a hard bake process for heating the wafer W after performing a development process, and a cooling process for cooling the heated wafer W after performing each bake process. The bake chamber 470 includes a cooling plate 471 or a heating plate 472. A cooling means 473 such as coolant or a thermoelectric device is provided to the cooling plate 471. Additionally, a heating means 474 such as a heating wire or a thermoelectric device is provided to the heating plate 472. The cooling plate 471 and the heating plate 472 may be separately provided in one bake chamber 470. Selectively, part of the bake chamber 470 may include only the cooling plate 471 and another part may include only the heating plate 472.

As mentioned above, the coating module 401 and the development module 402 are separately provided in the coating and development module 400. Additionally, the coating module 401 and the development module 402 may have the same chamber arrangement as seen from the top.

(Second Buffer Module)

The second buffer module 500 is provided as a path through which the wafer W is transferred between the coating and development module 400 and the pre/post-exposure treatment module 600. Moreover, the second buffer module 500 performs a predetermined process, for example, a cooling process or an edge exposure process on the wafer W. The second buffer module 500 includes a frame 510, a buffer 520, a first cooling chamber 530, a second cooling chamber 540, an edge exposure chamber 550, and a second buffer robot 560. The frame 510 has a rectangular parallelepiped form. The buffer 520, the first cooling chamber 530, the second cooling chamber 540, the edge exposure chamber 550, and the second buffer robot 560 are disposed in the frame 510. The buffer 520, the first cooling chamber 530, and the edge exposure chamber 550 are disposed at the height corresponding to the coating module 401. The second cooling chamber 540 is disposed at the height corresponding to the development module 402. The buffer 520, the first cooling chamber 530, and the second cooling chamber 540 are sequentially disposed in a line along the third direction 16. The buffer 520 and the conveying chamber 430 of the coating module 401 are disposed along the first direction 12 as seen from the top. The edge exposure chamber 550 is spaced a predetermined distance from the buffer 520 or the first cooling chamber 530 in the second direction 14.

The second buffer robot 560 transfers the wafer W between the buffer 520, the first cooling chamber 530, and the edge exposure chamber 550. The second buffer robot 560 is positioned between the edge exposure chamber 550 and the buffer 520. The second buffer robot 560 has a similar structure to the first buffer robot 560. The first cooling chamber 530 and the edge exposure chamber 550 perform a subsequent process on the wafers W where a process is performed by the coating module 401. The first cooling chamber 530 cools the wafers W where a process is performed by the coating module 401. The first cooling chamber 530 has a similar structure to the cooling chamber 350 of the first buffer module 300. The edge exposure chamber 550 exposes the edges of the wafers W where a cooling process is performed by the first cooling chamber 530. The buffer 520 temporarily stores the wafers W before the wafers W where a process is performed by the edge exposure chamber 550 are transferred to a pre-treatment module 601 described later. The second cooling chamber 540 cools the wafers W before the wafers W where a process is performed by the post-treatment module 602 described later is transferred to the development module 402. The second buffer module 500 may further include an additional buffer at the height corresponding to the development module 402. In this case, the wafers W where a process is performed by the post-treatment module 602 are temporarily stored in the additional buffer and then are transferred to the development module 402.

(Pre/Post-Exposure Treatment Module)

The pre/post-exposure treatment module 600 may perform a process for applying a protective layer to protect the photoresist layer coated on the wafer W during immersion exposure when the exposure device 900 performs an immersion exposure process. Additionally, the pre/post-exposure treatment module 600 may perform a process for cleaning the wafers W after the exposure. Additionally, when a coating process is performed by using a chemical amplification resist, the pre/post-exposure treatment module 600 may perform a bake process after the exposure.

The pre/post-exposure treatment module 600 includes a pre-treatment module 601 and a post-treatment module 602. The pre-treatment module 601 performs a process for treating the wafer W before performing an exposure process and the post-treatment module 602 performs a process for treating the wafer W after performing an exposure process. The pre-treatment module 601 and the post-treatment module 602 are disposed to be partitioned from each other by a layer. According to an embodiment of the present invention, the pre-treatment module 601 is disposed on the post-treatment module 602. The pre-treatment module 601 and the coating module 401 are provided at the same height. The post-treatment module 602 and the development module 402 are provided at the same height. The pre-treatment module 601 includes a protective layer coating chamber 610, a bake chamber 620, and a conveying chamber 630. The protective layer coating chamber 610, the conveying chamber 630, and the bake chamber 620 are sequentially disposed along the second direction 14. Accordingly, the protective layer coating chamber 610 and the bake chamber 620 are spaced from each other in the second direction with the conveying chamber 630 therebetween. A plurality of protective layer coating chambers 610 are provided and disposed along the third direction 16 to form respective layers. Selectively, the plurality of protective layer coating chambers 610 are provided in each of the first direction 12 and the third direction 16. A plurality of bake chambers 620 are provided and disposed along the third direction 16 to form respective layers. Selectively, the plurality of bake chambers 620 are provided in each of the first direction 12 and the third direction 16.

The conveying chamber 630 is positioned parallel to the first cooling chamber 530 of the second buffer module 500 in the first direction 12. A pre-treatment robot 632 is positioned in the conveying chamber 630. The conveying chamber 320 typically has a square or rectangular form. The pre-treatment robot 632 transfers the wafer W between the protective layer coating chambers 610, the bake chambers 620, the buffer 520 of the second buffer module 500, and the first buffer 720 of the interface module 700 described later. The pre-treatment robot 632 includes a hand 633, an arm 634, and a support 635. The hand 633 is fixedly installed to the arm 634. The arm 634 is provided with a stretchable structure and a rotatable structure. The arm 634 is coupled to the support 635 to linearly move along the support 635 in the third direction 16.

The protective layer coating chamber 610 applies on the wafer W a protective layer for protecting a photoresist layer during immersion exposure. The protective layer coating chamber 610 includes a housing 611, a support plate 612, and a nozzle 613. The housing 611 has a cup shape with an open top. The support plate 612 is disposed in the housing 611 and supports the wafer W. The support plate 612 is provided to be rotatable. The nozzle 613 supplies a protective solution to the top of the wafer W disposed on the support plate 612 so as to form a protective layer. The nozzle 613 has a circular pipe form and supplies a protective solution to the center of the wafer W. Selectively, the nozzle 613 may have a length corresponding to the diameter of the wafer W and a discharge port of the nozzle 613 may be provided as a slit. In this case, the support plate 612 may be provided in a fixed state. The protection solution includes a form material. The protective solution may include a photoresist and a material with low affinity to water. For example, the protection solution may include a fluorine-based solvent. The protective layer coating chamber 610 supplies a protective solution to the center area of the wafer W as rotating the wafer W disposed on the support plate 612.

The bake chamber 620 performs a thermal treatment on the wafer W where the protective layer is applied. The bake chamber 620 includes a cooling plate 621 or a heating plate 622. A cooling means 623 such as coolant or a thermoelectric device is provided to the cooling plate 621. Additionally, a heating means 624 such as a heating wire or a thermoelectric device is provided to the heating plate 622. The heating plate 622 and the cooling plate 621 may be separately provided in one bake chamber 620. Selectively, part of the bake chamber 620 may include only the heating plate 622 and another part may include only the cooling plate 621.

The post-treatment module 602 includes a cleaning chamber 660, a post exposure bake chamber 670, and a conveying chamber 680. The cleaning chamber 660, the conveying chamber 680, and the post exposure bake chamber 670 are sequentially disposed along the second direction 14. Accordingly, the cleaning chamber 660 and the post exposure bake chamber 670 are spaced from each other in the second direction with the conveying chamber 680 therebetween. A plurality of cleaning chambers 660 are provided and disposed along the third direction 16 to form respective layers. Selectively, the plurality of cleaning chambers 660 are provided in each of the first direction 12 and the third direction 16. A plurality of post exposure bake chambers 670 are provided and disposed along the third direction 16 to form respective layers. Selectively, the plurality of post exposure bake chambers 670 are provided in each of the first direction 12 and the third direction 16.

The conveying chamber 680 is positioned parallel to the second cooling chamber 540 of the second buffer module 500 in the first direction 12 as seen from the top. The conveying chamber 680 typically has a square or rectangular form. A post-treatment robot 682 is positioned in the conveying chamber 680. The post-treatment robot 682 transfers the wafer W between the cleaning chambers 660, the post exposure bake chambers 670, the second cooling chamber 540 of the second buffer module 500, and a second buffer 730 of an interface module 700 described later. The post-treatment robot 682 provided in the post-treatment module 602 may have the same structure as the pre-treatment robot 632 provided in the pre-treatment module 601.

The cleaning chamber 660 cleans the wafer W after an exposure process. The cleaning chamber 660 includes a housing 661, a support plate 662, and a nozzle 663. The housing 661 has a cup shape with an open top. The support plate 662 is disposed in the housing 661 and supports the wafer W. The support plate 662 is provided to be rotatable. The nozzle 663 supplies a cleaning solution to the top of the wafer W disposed on the support plate 662. Water such as deionized water may be used as the cleaning solution. The cleaning chamber 660 supplies a cleaning solution to the center area of the wafer W as rotating the wafer W disposed on the support plate 662. Selectively, while the wafer W rotates, the nozzle 663 may linearly or rotatably move from the center area to the edge area of the wafer W.

The post exposure bake chamber 670 heats the wafer W, where an exposure process is performed, by using ultraviolet. The post exposure bake process amplifies an acid generated in a photoresist through exposure by heating the wafer W, thereby completing of the property change of the photoresist. The post exposure bake chamber 670 includes a heating plate 672. A heating means 674 such as a heating wire or a thermoelectric device is provided to the heating plate 672. The post exposure bake chamber 670 includes a cooling plate 671 therein. A cooling means 673 such as coolant or a thermoelectric device is provided to the cooling plate 671. Additionally, a bake chamber including only the cooling plate 672 may be further provided selectively.

As mentioned above, the pre-treatment module 601 and the post-treatment module 602 are completely separated and provided to the post exposure treatment module 600. Additionally, the conveying chamber 630 of the pre-treatment module 601 and the conveying chamber 680 of the post-treatment module 602 are provided with the same size, so that they may overlap each other completely as seen from the top. Additionally, the protective layer coating chamber 610 and the cleaning chamber 660 are provided with the same size, so that they may overlap each other completely as seen from the top. Additionally, the bake chamber 620 and the post exposure bake chamber 670 are provided with the same size, so that they may overlap each other completely as seen from the top.

(Interface Module)

The interface module 700 transfers the wafer W between the pre/post-exposure treatment module 600, a fuzzy module 800, and an exposure device 900. The interface module 700 includes a frame 710, a first buffer 720, a second buffer 730, and an interface robot 740. The first buffer 720, the second buffer 730, and the interface robot 740 are disposed in the frame 710. The first buffer 720 and the second buffer 730 are spaced a predetermined distance from each other and disposed to be stacked each other. The first buffer 720 is disposed higher than the second buffer 730. The first buffer 720 is positioned at the height corresponding to the pre-treatment module 601 and the second buffer 730 is disposed at the height corresponding to the post-treatment module 602. As seen from the top, the first buffer 720 and the conveying chamber 630 of the pre-treatment module 601 are disposed in a line along the first direction 12 and the second buffer 730 and the conveying chamber 630 of the pre-treatment module 602 are disposed in a line along the first direction 12.

The interface robot 740 is spaced from the first buffer 720 and the second buffer 730 in the second direction 14. The interface robot 740 transfers the wafer W between the first buffer 720, the second buffer 730, the fuzzy module 800, and the exposure device 900. The interface robot 740 has a relatively similar structure to the second buffer robot 560.

The first buffer 720 temporarily stores the wafers W before the wafers W where a process is performed by the edge exposure chamber 720 are transferred to the exposure device 900. Then, the second buffer 730 temporarily stores the wafers W before the wafers W where a process is completed by the exposure device 900 are transferred to the post-treatment module 602. The first buffer 720 has a housing 721 and a plurality of supports 722. The supports 722 are disposed in the housing 721 and are provided spaced apart from each other in the third direction 16. One wafer W is disposed at each support 722. The housing 721 has an opening (not shown) in a direction where the interface robot 740 is provided and a direction where the pre-treatment robot 632 is provided, so as to allow the interface robot 740 and the pre-treatment robot 632 to carry the wafer W into or from the hosing 721. The second buffer 730 has a relatively similar structure to the first buffer 720. However, the hosing 4531 of the second buffer 730 has an opening (not shown) in a direction where the interface robot 740 is provided and in a direction where the post-treatment robot 682 is provided. An interface module may include only the above-mentioned buffers and robots without a chamber for performing a predetermined process on a wafer.

(Fuzzy Module)

The fuzzy module 800 may be disposed in the interface module 700. In more detail, the fuzzy module 800 may be disposed at the position facing the first buffer 720 on the basis of the interface robot 740. Unlike this, the fuzzy module 800 may be provided at various positions, for example, a position where the exposure device 900 at the rear end of the interface module 700 is connected or a side part of the interface module 700. The fuzzy module 800 performs a gas purge process and a rinse process on a wafer where a protective layer is applied through the pre/post-exposure treatment module 600 to protect a photoresist.

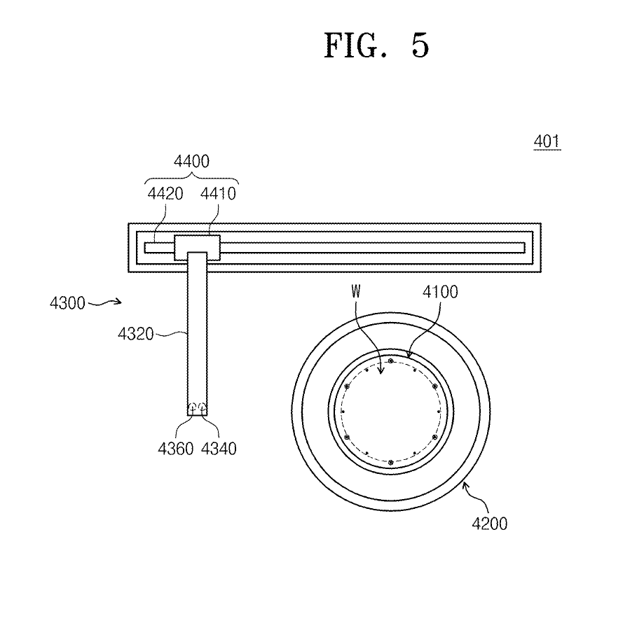

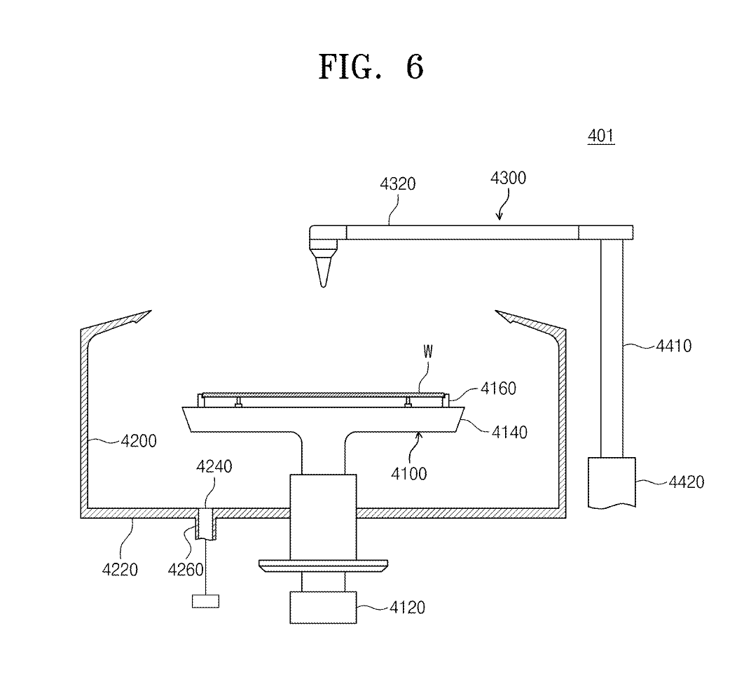

FIG. 5 is a plan view of a coating module according to an embodiment of the present invention. FIG. 6 is a cross-sectional view of the coating module of FIG. 5.

Referring to FIGS. 5 to 6, the coating module 401 includes a substrate support member 4100 and a treatment solution supply unit 4300. The substrate support member 4100 supports a substrate W. The substrate support member 4100 may rotate while supporting the substrate W. The treatment solution supply unit 4300 supplies a treatment solution to the top of the substrate W disposed on the substrate support member 4100 so as to treat the substrate W.

The substrate support member 4100 supports the substrate W and is rotated by the rotation driving member 4120 such as a motor during a process. The substrate support member 4100 has a support plate 4140 having a circular top surface and pin members 4160 supporting the substrate W are installed at the top surface of the support plate 4140. The substrate W supported by the pin members 4160 rotates as the substrate support member 4100 rotates by the rotation driving member 4120.

A container 4200 is disposed around the substrate support member 4100. The container 4200 typically has a cylindrical form. A discharge hole 4240 is formed at a lower wall 4220 and a discharge pipe 4260 communicates with the discharge pipe 4260. A discharge member 4280 such as a pump is connected to the discharge pipe 4260. The discharge member 4280 provides a pressure to discharge air in the container 4200 containing a treatment solution scattered by the rotation of the substrate W.

The treatment solution supply unit 4300 supplies a treatment solution to the top of the substrate W disposed on the substrate support member 4100. The treatment solution supply unit 4300 includes a nozzle arm 4320 provided at one side of the substrate support member 4100. A plurality of nozzles 4340 and 4360 may be mounted at the end of the nozzle arm 4320. The nozzles 4340 and 4360 may be disposed in a line at one end of the nozzle arm 4320 in vertical to the length direction of the nozzle arm 4320. One of the nozzles 4340 and 4360 is provided as a photoresist nozzle 4360 and the other one is provided as a pre-wet nozzle 4340. The nozzle arm 4320 may be disposed at one side of the substrate support member 4100 to allow the arrangement direction of the nozzles 4340 and 4360 to pass through the center of the substrate W disposed on the substrate support member 4100.

The photoresist nozzle 4360 supplies a photoresist to the substrate W. The pre-wet nozzle 4340 supplies an organic solvent to the substrate W in order to improve the wettability of the photoresist with respect to the substrate W before providing the photoresist to the substrate W. If the organic solvent is supplied before the photoresist is supplied on the substrate W, the photoresist is uniformly spread on the substrate W, so that a uniform photoresist layer may be formed on the substrate W.

The organic solvent supplied from the pre-wet nozzle 4340 to the substrate W may include a thinner.

The nozzle arm 4320 equipped with the plurality of nozzles 4340 and 4360 may linearly move by a driving member 4400 along the arrangement direction of the nozzles 4340 and 4360. The driving member 4400 includes a nozzle arm support member 4410 and a guide member 4420. A nozzle arm support member 4410 is coupled to the other end of the nozzle arm 4320. The nozzle arm support member 4410 may be provided in a rod form disposed in a downward direction at one side of the nozzle arm 4320. A lower part of the nozzle arm support member 4410 is connected to the guide member 4420. The guide member 4420 is disposed at one side of the substrate support member 4100 to be vertical to the length direction of the nozzle arm 4320 according to a planar arrangement structure. The guide member 4420 has a rail form and guides a linear movement of the nozzle arm support member 4410. The nozzle arm support member 4410 may be provided to be variable in a vertical length.

As moving linearly by the driving member 4400 having the above configuration, the treatment solution supply unit 4300 may move to a process position on the substrate support member 4100 and a process standby position provided at one side of the substrate support member 4100.

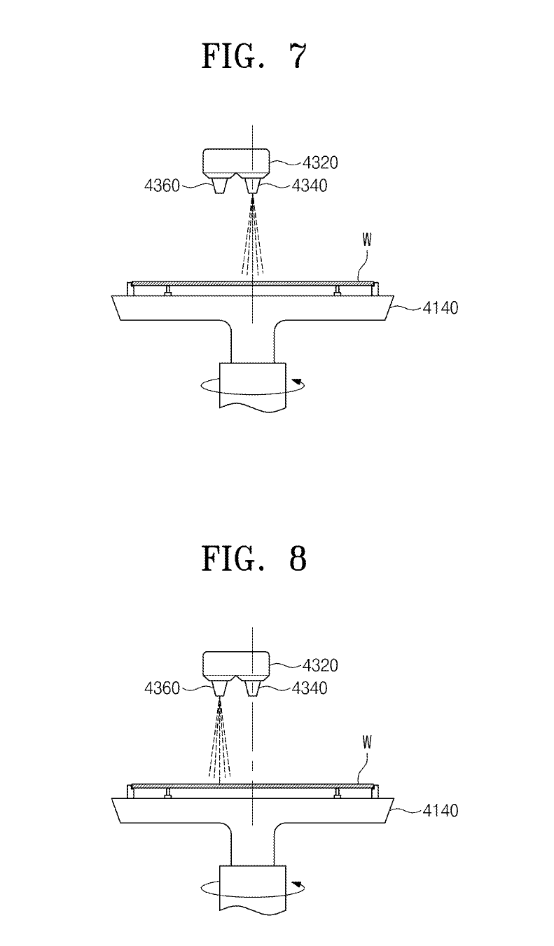

FIG. 7 is a front view when an organic solvent is supplied from a pre-wet nozzle during an organic solvent supply process.

Referring to FIGS. 5 to 7, the treatment solution supply unit 4300 supplies an organic solvent to the substrate W positioned at the substrate support member.

The driving member 4400 adjusts the position of the pre-wet nozzle 4340 with respect to the substrate W while the organic solvent is supplied. For example, the driving member 4400 may move the nozzle arm 4320 to allow the pre-wet nozzle 4340 to be positioned above the center of the substrate W. Accordingly, the pre-wet nozzle 4340 supplies an organic solvent to the center of the substrate W. While the organic solvent is supplied, the rotation driving member 4400 rotates the support plate 4140. Accordingly, as the organic solvent supplied to the substrate W is diffused by centrifugal force in a radial direction from the center of the substrate W and then is uniformly applied to the top surface of the substrate W. As another example, the pre-wet nozzle 4340 starts supplying an organic solvent at the off-center position of the substrate W. Then, the driving member 4400 moves the nozzle arm 4320 to allow the pre-wet nozzle 4340 to be positioned above the center of the substrate W while the organic solvent is supplied.

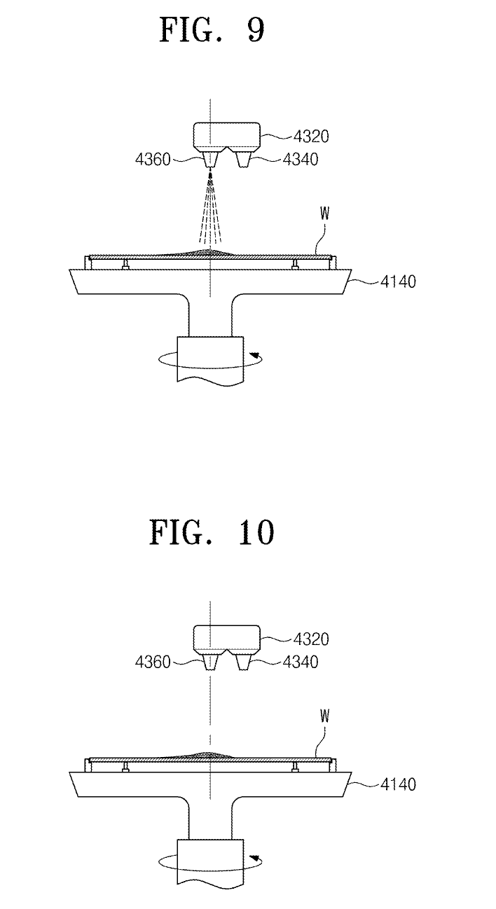

FIG. 8 is a front view when a photoresist is supplied during an eccentric supply process and FIG. 9 is a front view when a photoresist is supplied during a center supply process.

Referring to FIGS. 5 to 9, the treatment solution supply unit 4300 supplies an organic solvent to the substrate W during a predetermined time and then supplies a photoresist to the substrate W.

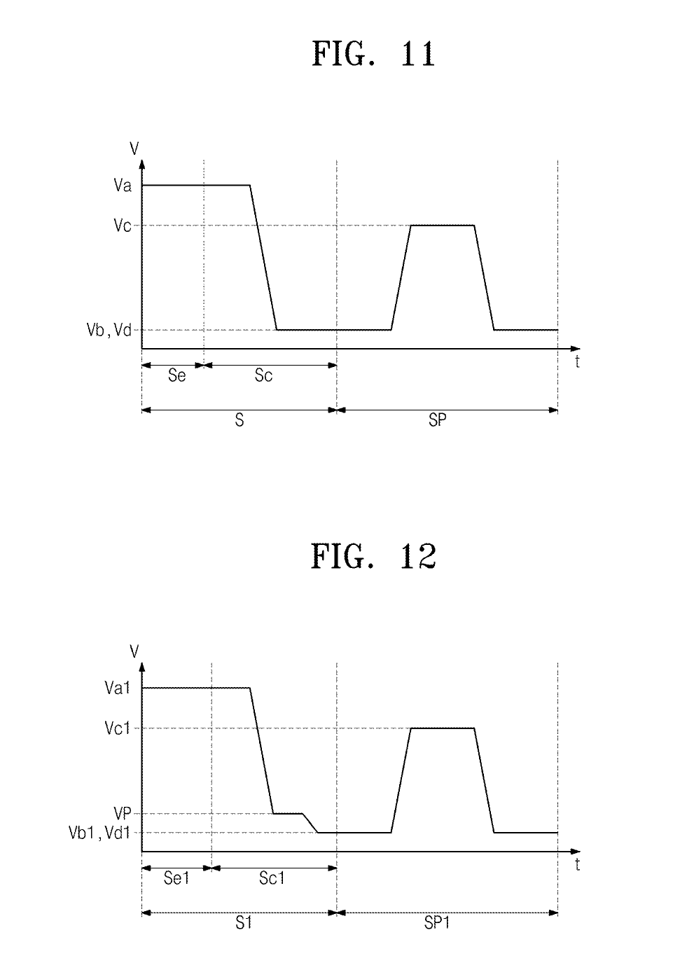

When the organic solvent is supplied during the predetermined time, the treatment solution supply unit 4300 starts supplying the photoresist solution. The photoresist supply stage S of FIG. 11 may include the eccentric supply state Se of FIG. 11 and the center supply stage Sc of FIG. 11.

The treatment solution supply unit 4300 starts supplying a photoresist to the eccentric supply stage Se. First, the driving member 4400 moves the nozzle arm 4360 to allow the photoresist nozzle 4360 to be positioned above the eccentric portion with respect to the center of the substrate W. Then, the photoresist nozzle 4360 starts supplying a photoresist to an eccentric portion from the center of the substrate W. In the eccentric supply stage Se, while the photoresist is supplied, the rotation driving member 4400 rotates the support plate 4140. Accordingly, the photoresist supplied to the substrate W is diffused around.

After the photoresist nozzle 4360 starts supplying a photoresist, the driving member 4400 moves the nozzle arm 4320 to allow the photoresist nozzle 4360 to be positioned above the center of the substrate W. The movement of the nozzle arm 4321 may start simultaneously as starting a photoresist supply. Additionally, the movement of the nozzle arm 4321 may start after starting a photoresist supply for a predetermined time.

The movement speed of the nozzle arm 4320 in the center direction of the substrate W may be constant speed. Additionally, the movement speed of the nozzle arm 4321 may vary over time. For example, the movement speed of the nozzle arm 4321 may be accelerated, constant, or decelerated according to the lapse of a predetermined time.

After the eccentric supply stage Se, according to the center supply state Sc, the treatment solution supply unit 4300 supplies a photoresist to the substrate W. In more detail, as the nozzle arm 4320 moves in the center direction of the substrate W, when the photoresist nozzle 4360 is positioned above the center of the substrate W, the driving member 4400 stops the nozzle arm 4320. After staring to supply a photoresist in the eccentric supply stage Se, the photoresist nozzle 4360 continuously supplies the photoresist to the substrate W in the eccentric supply stage Se and the center supply stage Sc.

While the photoresist is supplied in the center supply stage Sc, the rotation driving member 4400 rotates the support plate 4140. Accordingly, the photoresist supplied to the center of the substrate W is diffused around.

According to another embodiment of the present invention, the eccentric supply stage Se may be omitted. Accordingly, after an inorganic solvent supply to the substrate W is completed, the photoresist is supplied to the substrate W in the center supply stage Sc.

FIG. 10 is a front view illustrating a diffusion stage.

Referring to FIGS. 5 to 10, the diffusion stage SP starts as the photoresist supply stage S stops.

The photoresist nozzle 4360 stops the supply while supplying the photoresist to the center of the substrate W. In the diffusion stage after the photoresist supply stops, the rotation driving member 4400 rotates the support plate 4140 continuously. Accordingly, the photoresist supplied to the center of the substrate W is diffused continuously, so that the coating uniformity of the top surface of the substrate W becomes improved.

FIG. 11 is a graph illustrating the rotational speed of a support plate in a photoresist supply stage and a diffusion stage.

Referring to FIGS. 8 to 11, the rotational speed of the support plate 4140 varies over time.

In the eccentric supply stage Se, the support plate 4140 rotates at the constant speed of a first supply speed Va. The first supply speed Va may be identical to the rotational speed of the support plate 4140 during an organic solvent supply. Additionally, the first supply speed Va may be faster or slower than the rotational speed of the support plate 4140 during an organic solvent supply. After the eccentric supply stage Se stops, the rotational speed of the support plate 4140 is maintained for a predetermined time after the start of the center supply stage Sc.

After a photoresist solution is supplied for a predetermined time in the center supply stage Sc, the rotational speed of the support plate 4140 is decelerated from the first supply speed Va to the second supply speed Vb. The slope of the graph in an interval at which the support plate 4140 is decelerated from the first supply speed Va to the second supply speed Vb may be adjusted according to the size of the substrate W and the amount of a photoresist supplied to the substrate W. The center supply stage Sc is maintained for a predetermined time at the second supply speed Vb and then is terminated.

After/before the photoresist supply stops, a force applied to the top surface of the substrate W may be changed. Such a force is generated by a centrifugal force from the rotation of the support plate 4140, a force that the supplied photoresist is applied on the top surface of the substrate W, and an interaction thereof. After/before the photoresist supply stops, changes in such forces cause the disparity for each area of the photoresist supplied to the top surface of the substrate W. On the other hand, the coating module 401 according to an embodiment of the present invention stops the photoresist supply at the second supply speed Vb that is decelerated from the first supply speed Va. That is, while such forces that cause the disparity for each area of the photoresist are reduced, the photoresist supply is stopped. Accordingly, the disparity for each area of the photoresist, which occurs when the photoresist supply stops, may be minimized.

Additionally, the second supply speed Vb is set as a speed at which a portion of the photoresist is not scattered around and is gathered on the center of the substrate W. The photoresist gathered on the center may flow to fill the disparity for each area caused by a force occurring when the photoresist supply stops.

In the diffusion stage SP, the support plate 4140 is accelerated to allow the photoresist gathered on the center of the substrate W to be diffused around. In more detail, the support plate 4140 is accelerated from the second supply speed Vb to a diffusion speed Vc after a predetermined time. The diffusion speed Vc may be set according to the size of the substrate W and a process time in the coating module 401. For example, the diffusion speed Vc may be set to be less than the first supply speed Va. Additionally, the diffusion speed Vc may be set to be identical to or greater than first supply speed Va.

After the diffusion speed Vc is maintained for a predetermined time, the support plate 4140 is decelerated to a termination speed Vd. The termination speed Vd may be identical to the second supply speed Vb. Additionally, the termination speed Vd may be greater than or less than the second supply speed Vb. Then, when the support plate 4140 rotates at the terminal speed Vd for a predetermined time and stops, a photoresist coating process is terminated in a coating module.

FIG. 12 is a graph illustrating the rotational speed of a support plate according to another embodiment of the present invention.

Referring to FIG. 12, in a center supply stage Sc1, a deceleration from a first supply speed Va1 to a second supply speed Vb2 may be gradually performed. In more detail, the deceleration in the center supply stage Sc1 is from the first supply speed Va1 to a buffer speed VP. Then, the support plate 4140 rotates for a predetermined time at the buffer speed VP and then rotates at the second supply speed Vb2 again. At this point, the slope of the graph when the first supply speed Va1 is decelerated to the buffer speed VP may be set to be identical to the slope of the graph when the buffer speed VP is decelerated to the second supply speed Vb2. Additionally, the slope of the graph when the first supply speed Va1 is decelerated to the buffer speed VP may be set to be greater or less than the slope of the graph when the buffer speed VP is decelerated to the second supply speed Vb2. Additionally, the buffer speed VP may be set with an arithmetic average value of the first supply speed Va1 and the second supply speed Vb2. Additionally, the buffer speed VP may be set to be greater or less than an arithmetic average value of the first supply speed Va1 and the second supply speed Vb2. Additionally, although one buffer speed VP is positioned between the first supply speed Va1 and the second supply speed Vb2 as shown in FIG. 12, two buffer speeds VP are positioned, so that the deceleration of the support plate 4140 may be achieved through more than two stages.

According to an embodiment of the present invention, a substrate may be treated uniformly.

Furthermore, according to an embodiment of the present invention, a photoresist may be applied to a substrate uniformly.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate treatment device comprising:
a substrate support member configured to support a substrate to be treated;
a rotation driving member rotating the substrate support member;
a container provided around the substrate support member; and
a treatment solution supply unit including a photoresist nozzle for supplying a photoresist to a top surface of the substrate,
wherein the photoresist nozzle starts supplying the photoresist while the substrate support member rotates at a first supply speed and stops supplying the photoresist while the substrate support member rotates at a second supply speed decelerated from the first supply speed.

2. The device of claim 1, wherein the rotation driving member rotates the substrate support member at a diffusion speed accelerated from the second supply speed after the photoresist supply is terminated.

3. The device of claim 2, wherein the diffusion speed is set to be less than the first supply speed and greater than the second supply speed.

4. The device of claim 2, wherein the rotation driving member rotates the substrate support member at a termination speed decelerated from the diffusion speed and then stops the substrate support member.

5. The device of claim 1, wherein the rotation driving member gradually reduces a rotational speed of the substrate support member from the first supply speed to the second supply speed.

6. The device of claim 5, wherein the rotation driving member rotates the substrate support member at a buffer speed for a predetermined time while the first supply speed is decelerated to the second supply speed.

7. The device of claim 1, wherein the treatment solution supply unit comprises:
a nozzle arm having one end where the photoresist nozzle is positioned; and
a driving member moving the nozzle arm with respect to the substrate support member,
wherein the stop of the photoresist supply is made when the driving member positions the nozzle arm to allow the photoresist nozzle to be positioned above the center of the substrate.

8. The device of claim 7, wherein the start of the photoresist supply is made when the driving member positions the nozzle arm to allow the photoresist nozzle to be positioned eccentrically above the center of the substrate.

9. The device of claim 8, wherein after the start of the photoresist supply, the driving member moves the nozzle arm to allow the photoresist nozzle to be positioned above the center of the substrate.

10. The device of claim 9, wherein the photoresist nozzle supplies the photoresist for a predetermined time as being positioned above the center of the substrate.

11. The device of claim 1, wherein the treatment solution supply unit further comprises a pre-wet nozzle for supplying an organic solvent to the substrate.

12. The device of claim 11, wherein the pre-wet nozzle supplies the organic solvent to the substrate before the photoresist supply.

13. The device of claim 11, wherein the treatment solution supply unit supplies the organic solvent to the substrate while the pre-wet nozzle is positioned above the center of the substrate.

14. A method of applying a treatment solution, the method comprising:
starting to supply a photoresist to a top surface of a substrate supported by a substrate support member rotating at a first supply speed; and
stopping the photoresist supply while the substrate support member is decelerated from the first supply speed to a second supply speed.

15. The method of claim 14, further comprising, after the photoresist supply is terminated, rotating the substrate support member at a diffusion speed accelerated from the second supply speed and diffuses the photoresist gathered on a center portion of the substrate to a periphery of the center.

16. The method of claim 15, further comprising rotating the substrate support member for a predetermined time at a termination speed decelerated from the diffusion speed and stopping the rotation.

17. The method of claim 14, further comprising gradually decelerating the first supply speed to the second supply speed.

18. The method of claim 14, wherein the photoresist supply starts from a position eccentric from the center of the substrate and moves to the center of the substrate.

19. The method of claim 14, wherein the photoresist supply stops while the photoresist is supplied to the center of the substrate.
